(19) United States
(12) Patent Application Publication
(10) Pub. No.: US 2023/0058002 A1
(43) Pub. Date: Feb. 23, 2023

(54) METHODS OF PREPARING LENS ARRAYS, DISPLAY APPARATUSES, AND METHODS OF PREPARING DISPLAY APPARATUSES

(71) Applicant: BOE Technology Group Co., Ltd., Beijing (CN)

(72) Inventors: Haitao HUANG, Beijing (CN); Shi SHU, Beijing (CN); Qi YAO, Beijing (CN); Renquan GU, Beijing (CN); Zhao CUI, Beijing (CN); Chuanxiang XU, Beijing (CN)

(21) Appl. No.: 17/795,069

(22) PCT Filed: Jun. 8, 2021
(86) PCT No.: PCT/CN2021/098994

§ 371 Date: Jul. 25, 2022

(30) Foreign Application Priority Data
Jun. 15, 2020 (CN) 202010542730.X

(51) Int. Cl. H01L 51/52; H01L 27/32; H01L 51/56

(52) U.S. Cl. CPC H01L 51/5275; H01L 27/322; H01L 51/5253; H01L 51/56

(57) ABSTRACT

Disclosed are methods of preparing lens arrays, display apparatuses, and methods of preparing display apparatuses. A method of preparing a lens array includes: forming a hybrid film on a base substrate, the hybrid film including first hybrid sub-films arranged in an array and a second hybrid sub-film, and a contact angle of a liquid on a surface of the first hybrid sub-film being less than a contact angle of the liquid on a surface of the second hybrid sub-film; coating the hybrid film with a photo-curable resin to form liquid droplets arranged in an array, the liquid droplets being lens-shaped and located on the first hybrid sub-films, respectively; and photo-curing the photo-curable resin to obtain lenses arranged in an array, the lenses being located on the first hybrid sub-films, respectively.

### CROSS-REFERENCE TO RELATED APPLICATIONS

This disclosure claims priority to Chinese Patent Application No. 202010542730.X filed on Jun. 15, 2020 and entitled “METHODS OF PREPARING LENS ARRAYS, DISPLAY APPARATUSES, AND METHODS OF PREPARING DISPLAY APPARATUSES”, which is incorporated herein by reference in its entirety.

### TECHNICAL FIELD

The present disclosure relates to the field of display technology, and in particular to methods of preparing lens arrays, display apparatuses, and methods of preparing display apparatuses.

### BACKGROUND

In the related art, Micro OLED (Organic Light-Emitting Diode) devices use monocrystalline silicon wafers as backplanes, making them easier to achieve excellent characteristics such as high PPI (Pixels Per Inch, pixel density), small size, easy portability, and low power consumption, in addition to OLED self-luminescence, thin thickness, large viewing angle, short response time, and high luminous efficiency, and especially suitable for applications in AR (Augmented Reality) or VR (Virtual Reality) display devices such as head-mounted displays (HMDs), stereoscopic display glasses, and glasses-type displays.

### SUMMARY

The present disclosure provides a method of preparing a lens array, a display apparatus, and a method of preparing a display apparatus.

According to a first aspect of embodiments of the present disclosure, there is provided a method of preparing a lens array, including:

forming a hybrid film on a base substrate, the hybrid film including first hybrid sub-films arranged in an array and a second hybrid sub-film, and a contact angle of a liquid on a surface of the first hybrid sub-film being less than a contact angle of the liquid on a surface of the second hybrid sub-film;

coating the hybrid film with a photo-curable resin to form liquid droplets arranged in an array, the liquid droplets being lens-shaped and located on the first hybrid sub-films, respectively; and

photo-curing the photo-curable resin to obtain lenses arranged in an array, the lenses being located on the first hybrid sub-films, respectively.

In an embodiment, forming the hybrid film on the base substrate includes:

forming a first film on the base substrate;

forming a second film on the first film, the second film including first areas arranged in an array and a second area; and

exposing the first areas and the second area, respectively, such that a material of the first film is polymerized with a material of the second film to obtain the hybrid film, a duration during which the first area is exposed being longer than a duration during which the second area is exposed, and the first hybrid sub-films being respectively located in the first areas and the second hybrid sub-film being located in the second area.

In an embodiment, the first film is made of polyethylene terephthalate, polycarbonate or polyimide, and the second film is made of acrylic acid or acrylamide.

In an embodiment, the duration during which the first area is exposed is 3 s to 13 s, and the duration during which the second area is exposed is 0.2 s to 1.1 s.

In an embodiment, a light irradiance for exposure of the first areas and the second area is 30 mW/cm² to 80 mW/cm².

In an embodiment, the contact angle of the liquid on the surface of the first hybrid sub-film is 10 degrees to 50 degrees, and the contact angle of the liquid on the surface of the second hybrid sub-film is 60 degrees to 90 degrees.

According to a second aspect of embodiments of the present disclosure, there is provided a method of preparing a display apparatus, including the method of preparing the lens array according to any one of the above embodiments.

In an embodiment, the method of preparing the display apparatus further includes:

after photo-curing the photo-curable resin to obtain the lenses arranged in an array, forming a protective layer on the lenses arranged in an array.

In an embodiment, the method of preparing the display apparatus further includes:

before forming the hybrid film on the base substrate, forming a plurality of sub-pixels arranged in an array on the base substrate, where a non-display area exists between adjacent sub-pixels; the hybrid film is located on a side of the plurality of sub-pixels arranged in an array away from the base substrate; and a projection of the sub-pixels on the base substrate is located within a projection of the first hybrid sub-films on the base substrate, and a projection of the second hybrid sub-film on the base substrate is located within a projection of the non-display area on the base substrate.

In an embodiment, the method of preparing the display apparatus further includes:

before forming the hybrid film on the base substrate, forming an encapsulation layer on the plurality of sub-pixels arranged in an array, the encapsulation layer being located between the sub-pixels and the hybrid film.

In an embodiment, the plurality of sub-pixels include sub-pixels with at least one color; and the method of preparing the display apparatus further includes:

after forming the encapsulation layer on the plurality of sub-pixels arranged in an array, forming a color film on the encapsulation layer, where the color film is located between the encapsulation layer and the hybrid film, and includes a black matrix and filters with at least one color; the black matrix is located between adjacent filters; colors of the sub-pixels are in a one-to-one correspondence with colors of the filters; and for a same color, the projection of the sub-pixels on the base substrate is located within a projection of the filters on the base substrate, and a projection of the black matrix on the base substrate is located within the projection of the non-display area on the base substrate.

According to a third aspect of embodiments of the present disclosure, there is provided a display apparatus, including:

a base substrate;

a plurality of sub-pixels arranged in an array and located on the base substrate, a non-display area existing between adjacent sub-pixels;

a hybrid film located on a side of the plurality of sub-pixels arranged in an array away from the base substrate, where the hybrid film includes first hybrid sub-films arranged in an array and a second hybrid sub-film, and a contact angle of a liquid on a surface of the first hybrid sub-film is less than a contact angle of the liquid on a surface of the second hybrid sub-film; and a projection of the sub-pixels on the base substrate is located within a projection of the first hybrid sub-films on the base substrate, and a projection of the second hybrid sub-film on the base substrate is located within a projection of the non-display area on the base substrate; and

lenses arranged in an array and respectively located on the first hybrid sub-films.

According to the above embodiments, since the formed hybrid film includes the first hybrid sub-films arranged in an array and the second hybrid sub-film, and the contact angle of the liquid on the surface of the first hybrid sub-film is less than the contact angle of the liquid on the surface of the second hybrid sub-film, after the hybrid film is coated with the photo-curable resin, the liquid droplets arranged in an array may be formed on a surface of the hybrid film using the photo-curable resin through a physical repulsion between interfaces with different contact angles, where the liquid droplets are located on the first hybrid sub-films, respectively. Then, the lenses arranged in an array may be obtained by photo-curing the photo-curable resin.

It should be understood that the foregoing general description and the following detailed description are exemplary and explanatory only, and are not intended to limit the present disclosure.

### BRIEF DESCRIPTION OF THE DRAWINGS

The accompanying drawings, which are incorporated into and constitute a part of this specification, illustrate embodiments consistent with the present disclosure and together with the specification serve to explain the principle of the present disclosure.

FIG. 1 is a schematic structural diagram illustrating a display apparatus according to an embodiment of the present disclosure.

FIG. 2 is a schematic structural diagram illustrating a lens according to an embodiment of the present disclosure.

FIG. 3 is a flowchart illustrating a method of preparing a lens array according to an embodiment of the present disclosure.

FIG. 4 is another flowchart illustrating a method of preparing a lens array according to an embodiment of the present disclosure.

FIG. 5 is a flowchart illustrating a method of preparing a display apparatus according to an embodiment of the present disclosure.

FIGS. 6 to 9 are schematic structural diagrams illustrating intermediate structures produced during preparation of a display apparatus according to an embodiment of the present disclosure.

FIG. 10 is another flowchart illustrating a method of preparing a display apparatus according to an embodiment of the present disclosure.

FIGS. 11 to 13 are schematic structural diagrams illustrating intermediate structures produced during preparation of a display apparatus according to an embodiment of the present disclosure.

FIG. 14 is a schematic structural diagram illustrating a hybrid film according to an embodiment of the present disclosure.

FIG. 15 is an SEM image illustrating a lens according to an embodiment of the present disclosure.

### DETAILED DESCRIPTION OF THE EMBODIMENTS

Exemplary embodiments will be described herein in detail, examples of which are illustrated in the drawings. When the following description involves the drawings, like numerals in different drawings refer to like or similar elements unless otherwise indicated. Embodiments described in the following exemplary embodiments do not represent all embodiments consistent with the present disclosure. Rather, they are merely examples of apparatuses and methods consistent with some aspects of the present disclosure as detailed in the appended claims.

Micro OLED (Organic Light-Emitting Diode) display apparatuses generally suffer from a dim display due to low brightness. Conventionally, display brightness of the Micro OLED display apparatus may be enhanced by using a lens array to converge light emitted from sub-pixels. However, the lens array in the related art has a complicated preparation process and a high preparation cost, and is not conducive to mass production.

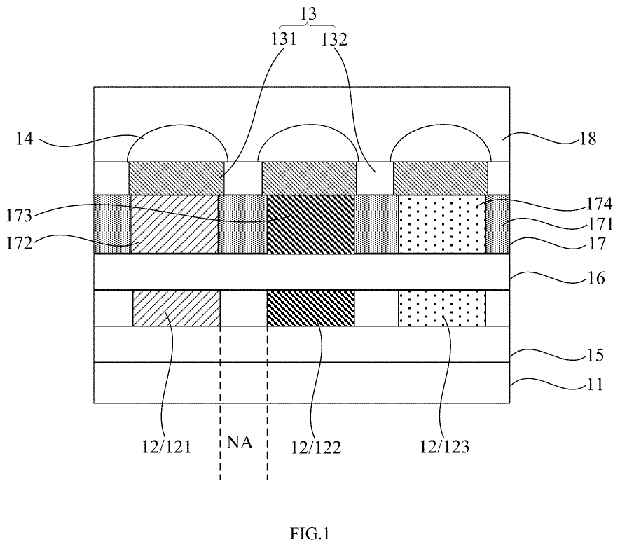

Embodiments of the present disclosure provide a display apparatus. As shown in FIG. 1, the display apparatus includes a base substrate 11, a plurality of sub-pixels 12 arranged in an array, a hybrid film 13, and lenses 14 arranged in an array.

In an embodiment, the display apparatus may be a Micro OLED display apparatus. The base substrate 11 may be a monocrystalline silicon wafer. Therefore, the Micro OLED display apparatus may also be referred to as a silicon-based OLED display apparatus.

As shown in FIG. 1, the plurality of sub-pixels 12 arranged in an array are located on the base substrate 11, with a non-display area NA existing between adjacent sub-pixels 12. The hybrid film 13 is located on a side of the plurality of sub-pixels 12 arranged in an array away from the base substrate 11. The hybrid film 13 includes first hybrid sub-films 131 arranged in an array and a second hybrid sub-film 132, and a contact angle of a liquid on a surface of the first hybrid sub-film 131 is less than a contact angle of the liquid on a surface of the second hybrid sub-film 132. A projection of the sub-pixels 12 on the base substrate 11 is located within a projection of the first hybrid sub-films 131 on the base substrate 11, and a projection of the second hybrid sub-film 132 on the base substrate 11 is located within a projection of the non-display area NA on the base substrate 11. The lenses 14 are located on the first hybrid sub-films 131, respectively.

In an embodiment, the contact angle of the liquid on the surface of the first hybrid sub-film 131 may be 10 degrees to 50 degrees, for example, 10 degrees, 20 degrees, 30 degrees, 40 degrees, or 50 degrees.

In an embodiment, the contact angle of the liquid on the surface of the second hybrid sub-film 132 may be 60 degrees to 90 degrees, for example, 60 degrees, 70 degrees, 75 degrees, 80 degrees, or 90 degrees.

In an embodiment, the display apparatus may further include a drive circuit layer 15 located on the base substrate 11. The drive circuit layer 15 may include a pixel circuit (not shown) for the sub-pixels 12, which is configured to drive the sub-pixels 12 to emit light.

In an embodiment, each sub-pixel 12 may include an anode, an organic light-emitting layer, and a cathode. The anode is located on the drive circuit layer 15, the organic light-emitting layer is located on the anode, and the cathode is located on the organic light-emitting layer. Anodes of the individual sub-pixels 12 may not be connected with each other, and cathodes of the individual sub-pixels 12 may be connected with each other to form a surface electrode.

In an embodiment, the plurality of sub-pixels 12 arranged in an array may include red sub-pixels 121, green sub-pixels 122, and blue sub-pixels 123. The red sub-pixels 121 are configured to emit red light, the green sub-pixels 122 are configured to emit green light, and the blue sub-pixels 123 are configured to emit blue light.

In an embodiment, as shown in FIG. 1, the display apparatus may further include an encapsulation layer 16 covering the plurality of sub-pixels 12 arranged in an array. The encapsulation layer 16 is configured to block water and oxygen to protect the sub-pixels 12. The encapsulation layer 16 may include a first inorganic layer, an organic layer, and a second inorganic layer. The first inorganic layer is located on the plurality of sub-pixels 12 arranged in an array, the organic layer is located on the first inorganic layer, and the second inorganic layer is located on the organic layer. The first inorganic layer may be made of silicon nitride, the organic layer may be made of polymethyl methacrylate (PMMA), and the second inorganic layer may be made of silicon oxynitride, but is not limited thereto.

In an embodiment, as shown in FIG. 1, the display apparatus may further include a color film 17 located on the encapsulation layer 16. The color film 17 may include a black matrix 171, red filters 172, green filters 173, and blue filters 174. A projection of the red sub-pixels 121 on the base substrate 11 is located within a projection of the red filters 172 on the base substrate 11, a projection of the green sub-pixels 122 on the base substrate 11 is located within a projection of the green filters 173 on the base substrate 11, and a projection of the blue sub-pixels 123 on the base substrate 11 is located within a projection of the blue filters 174 on the base substrate 11. The black matrix 171 is located between adjacent filters. A projection of the black matrix 171 on the base substrate 11 is located within the projection of the non-display area NA on the base substrate 11. In this embodiment, the color film 17 can reduce a reflectivity of ambient light, can prevent the ambient light from affecting a display effect, and can also prevent a user from viewing internal components of the display apparatus to affect a viewing experience when the display apparatus is not displaying a picture.

In an embodiment, as shown in FIG. 1, the display apparatus may further include a protective layer 18 covering the lenses 14. The protective layer 18 may be made of polymethyl methacrylate (PMMA), but is not limited thereto.

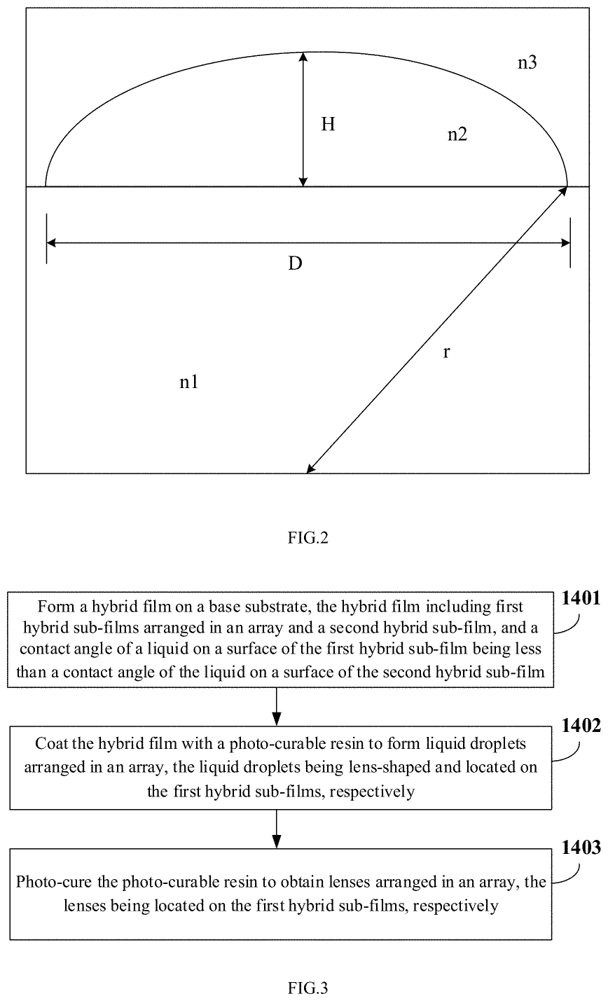

In an embodiment, as shown in FIG. 2, the lens may be plano-convex, and include a plane which may be circular and a curved surface. The lens may satisfy the following conditions:

$$f = \frac{{n}_{1} r}{{n}_{2} - {n}_{3}} \\ r = \frac{f * ( {n}_{2} - {n}_{3} )}{{n}_{1}} \\ {n}_{3} = {n}_{2} - \frac{r * {n}_{1}}{f} \\ Δ n = {n}_{2} - {n}_{3} = \frac{r * {n}_{1}}{f} \\ Δ n \geq \frac{{n}_{1} * D}{2 f} \\ r \geq \frac{D}{2} \\ Δ n ∝ D \\ Δ n ∝ \frac{1}{f}$$

where, as shown in FIG. 2, f is a focal length of the lens, n₁ is an average refractive index of all film layers between the sub-pixel 12 and the lens 14, n₂ is a refractive index of the lens, n₃ is a refractive index of the protective layer 18, r is a radius of curvature of the curved surface of the lens, D is a diameter of the plane of the lens, and H is the maximum thickness of the lens, that is, a thickness at the thickest position of the lens. A lens that satisfies the above conditions may have a convergence effect on light emitted from the sub-pixel.

It should be noted that, the closer a refractive index of each film layer between the sub-pixel 12 and the lens 14 is to the average refractive index, the better.

In this embodiment, since the lens is located above the sub-pixel and the lens has a convergence effect on light emitted from the sub-pixel, brightness of the light emitted from the sub-pixel can be increased, and thus brightness of the display apparatus can be increased.

According to this embodiment, since the hybrid film includes the first hybrid sub-films arranged in an array and the second hybrid sub-film, and the contact angle of the liquid on the surface of the first hybrid sub-film is less than the contact angle of the liquid on the surface of the second hybrid sub-film, during preparation of the lenses arranged in an array (a lens array), the hybrid film may be coated with a photo-curable resin, and liquid droplets arranged in an array may be formed on a surface of the hybrid film using the photo-curable resin through a physical repulsion between interfaces with different contact angles, where the liquid droplets are located on the first hybrid sub-films, respectively. Then, the lenses arranged in an array may be obtained by photo-curing the photo-curable resin.

The display apparatus according to embodiments of the present disclosure has been described above, and a method of preparing a lens array in the display apparatus and a method of preparing the display apparatus will be described below.

Embodiments of the present disclosure further provide a method of preparing a lens array. As shown in FIG. 3, the method of preparing the lens array includes steps 1401 to 1403.

At step 1401, a hybrid film is formed on a base substrate. The hybrid film includes first hybrid sub-films arranged in an array and a second hybrid sub-film, and a contact angle of a liquid on a surface of the first hybrid sub-film is less than a contact angle of the liquid on a surface of the second hybrid sub-film.

At step 1402, the hybrid film is coated with a photo-curable resin to form liquid droplets arranged in an array. The liquid droplets are lens-shaped and located on the first hybrid sub-films, respectively.

At step 1403, the photo-curable resin is photo-cured to obtain lenses arranged in an array. The lenses are located on the first hybrid sub-films, respectively.

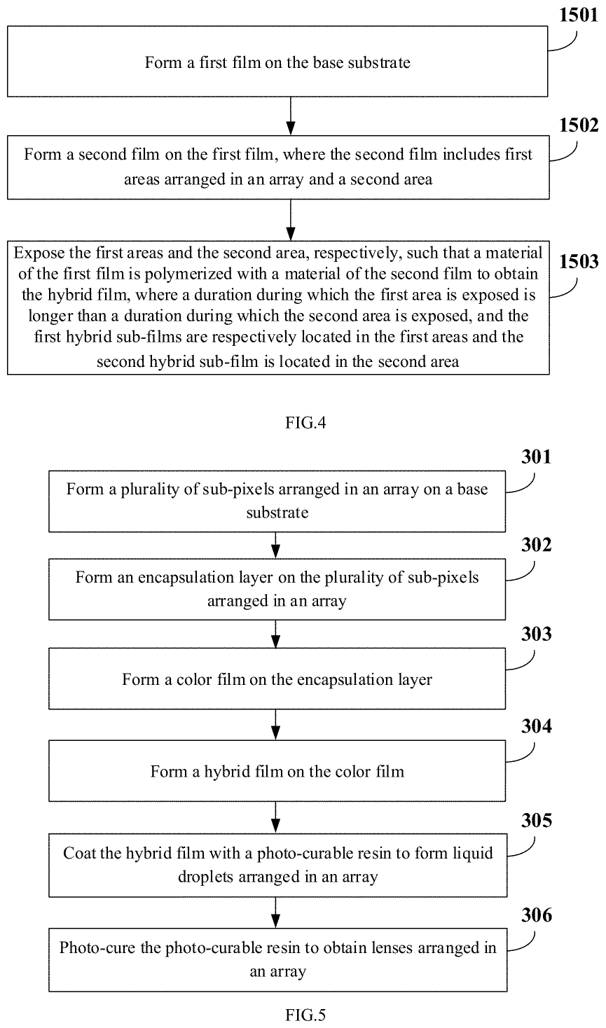

In an embodiment, as shown in FIG. 4, step 1401 may include steps 1501 to 1503.

At step 1501, a first film is formed on the base substrate.

At step 1502, a second film is formed on the first film, where the second film includes first areas arranged in an array and a second area.

At step 1503, the first areas and the second area are exposed, respectively, such that a material of the first film is polymerized with a material of the second film to obtain the hybrid film, where a duration during which the first area is exposed is longer than a duration during which the second area is exposed, and the first hybrid sub-films are respectively located in the first areas and the second hybrid sub-film is located in the second area.

In an embodiment, the first film may be made of polyethylene terephthalate, polycarbonate or polyimide.

In an embodiment, the second film may be made of acrylic acid or acrylamide.

In an embodiment, the duration during which the first area is exposed may be 3 s (seconds) to 13 s, and the duration during which the second area is exposed may be 0.2 s to 1.1 s.

In an embodiment, a light irradiance for exposure of the first areas and the second area may be 30 mW/cm² to 80 mW/cm².

In an embodiment, the contact angle of the liquid on the surface of the first hybrid sub-film may be 10 degrees to 50 degrees, and the contact angle of the liquid on the surface of the second hybrid sub-film may be 60 degrees to 90 degrees.

The method of preparing the lens array according to this embodiment may be used to prepare the display apparatus according to any one of the above embodiments.

According to this embodiment, since the formed hybrid film includes the first hybrid sub-films arranged in an array and the second hybrid sub-film, and the contact angle of the liquid on the surface of the first hybrid sub-film is less than the contact angle of the liquid on the surface of the second hybrid sub-film, after the hybrid film is coated with the photo-curable resin, the liquid droplets arranged in an array may be formed on a surface of the hybrid film using the photo-curable resin through a physical repulsion between interfaces with different contact angles, where the liquid droplets are located on the first hybrid sub-films, respectively. Then, the lenses arranged in an array may be obtained by photo-curing the photo-curable resin. With the technical solution according to this embodiment, the lens array has a simplified preparation process and a reduced preparation cost, which is conducive to mass production.

Embodiments of the present disclosure further provide a method of preparing a display apparatus, including the method of preparing the lens array according to any one of the above embodiments.

The method of preparing the display apparatus will be described in detail below with reference to FIGS. 5 to 15.

In an embodiment, as shown in FIG. 5, the method of preparing the display apparatus may include steps 301 to 306.

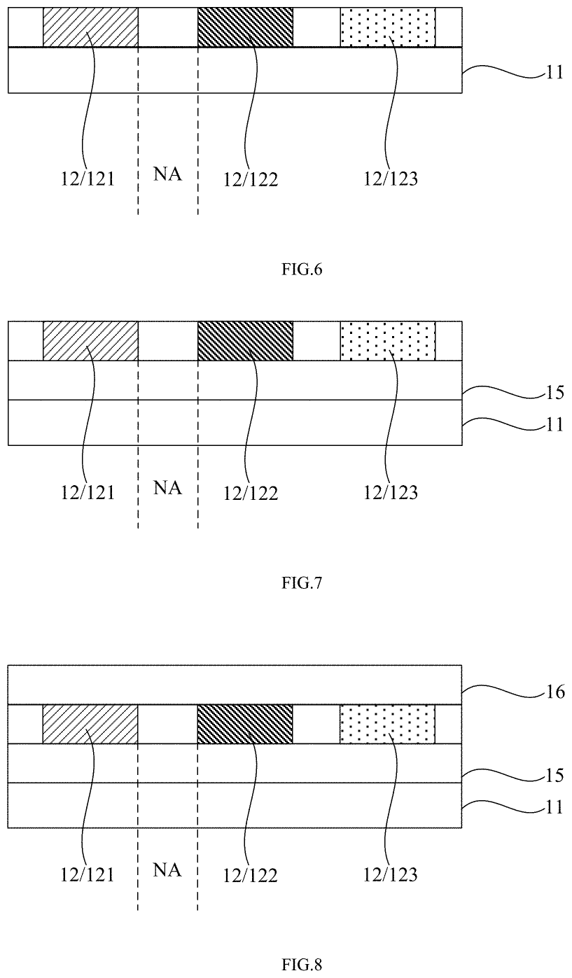

At step 301, a plurality of sub-pixels 12 arranged in an array are formed on a base substrate 11 to obtain an intermediate structure as shown in FIG. 6.

In this embodiment, as shown in FIG. 6, red sub-pixels 121, green sub-pixels 122, and blue sub-pixels 123 arranged in an array may be formed on the base substrate 11. A non-display area NA exists between adjacent sub-pixels 12. For example, the non-display area NA may exist between the red sub-pixel 121 and the green sub-pixel 122, and the non-display area NA may exist between the green sub-pixel 122 and the blue sub-pixel 123.

In an embodiment, during preparation of the red sub-pixel 121, a corresponding first organic light-emitting layer may be formed on an anode of the red sub-pixel 121. During preparation of the green sub-pixel 122, a corresponding second organic light-emitting layer may be formed on an anode of the green sub-pixel 122. During preparation of the blue sub-pixel 123, a corresponding third organic light-emitting layer may be formed on an anode of the blue sub-pixel 123.

In an embodiment, the method of preparing the display apparatus may further include: before step 301, forming a drive circuit layer 15 on the base substrate 11 to obtain an intermediate structure as shown in FIG. 7.

At step 302, an encapsulation layer 16 is formed on the plurality of sub-pixels 12 arranged in an array to obtain an intermediate structure as shown in FIG. 8.

At step 303, a color film 17 is formed on the encapsulation layer 16 to obtain an intermediate structure as shown in FIG. 9.

As shown in FIG. 9, the color film 17 includes a black matrix 171, red filters 172, green filters 173, and blue filters 174. The black matrix 171 is located between adjacent filters. A projection of the black matrix 171 on the base substrate 11 is located within a projection of the non-display area NA on the base substrate 11.

At step 304, a hybrid film 13 is formed on the color film 17. The hybrid film 13 includes first hybrid sub-films 131 arranged in an array and a second hybrid sub-film 132, and a contact angle of a liquid on a surface of the first hybrid sub-film 131 is less than a contact angle of the liquid on a surface of the second hybrid sub-film 132. A projection of the sub-pixels 12 on the base substrate 11 is located within a projection of the first hybrid sub-films 131 on the base substrate 11, and a projection of the second hybrid sub-film 132 on the base substrate 11 is located within the projection of the non-display area NA on the base substrate 11.

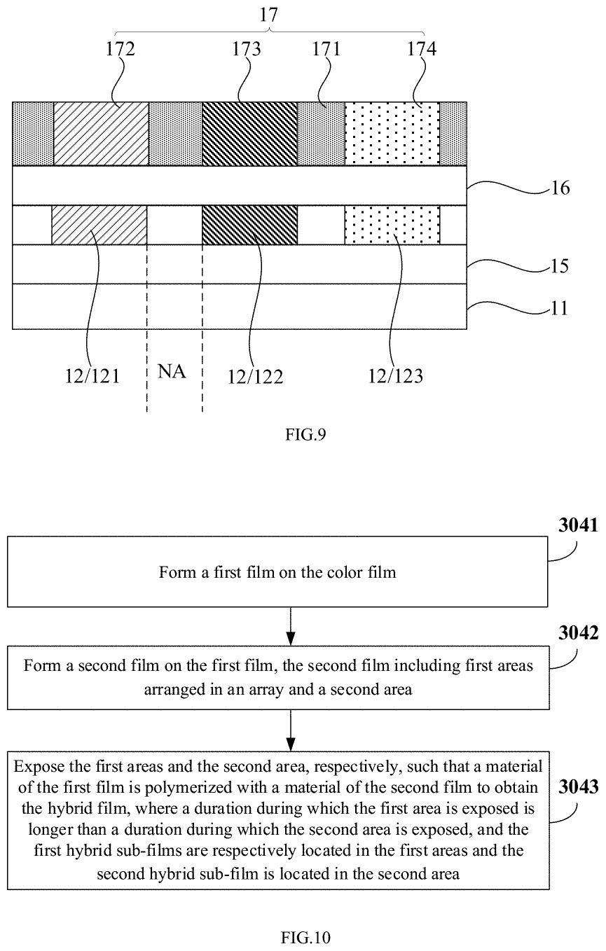

In this embodiment, as shown in FIG. 10, step 304 may include steps 3041 to 3043.

At step 3041, a first film 133 is formed on the color film 17 to obtain an intermediate structure as shown in FIG. 11.

As shown in FIG. 11, the first film 133 is located on the color film 17. The first film 133 may be made of polyethylene terephthalate (PET), polycarbonate or polyimide. In this embodiment, the first film 133 is made of PET.

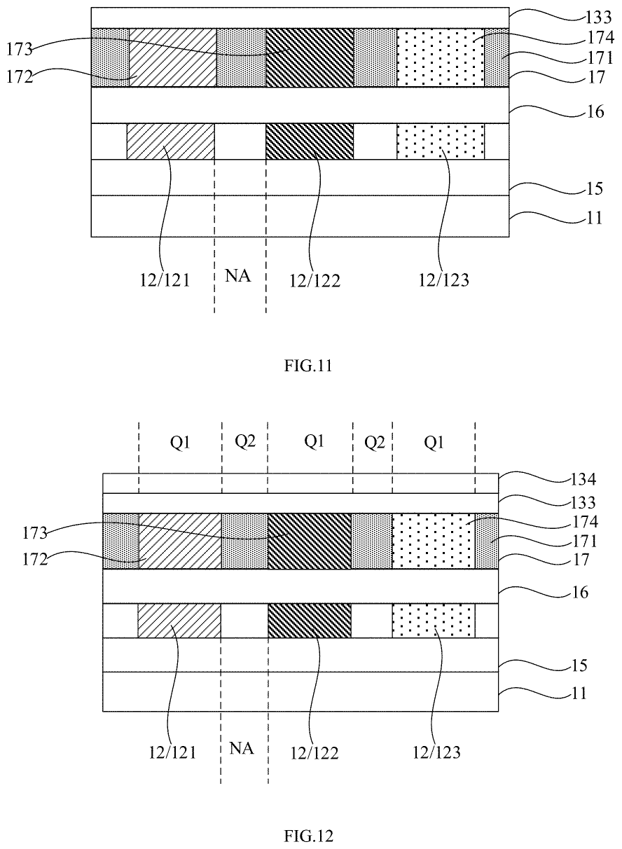

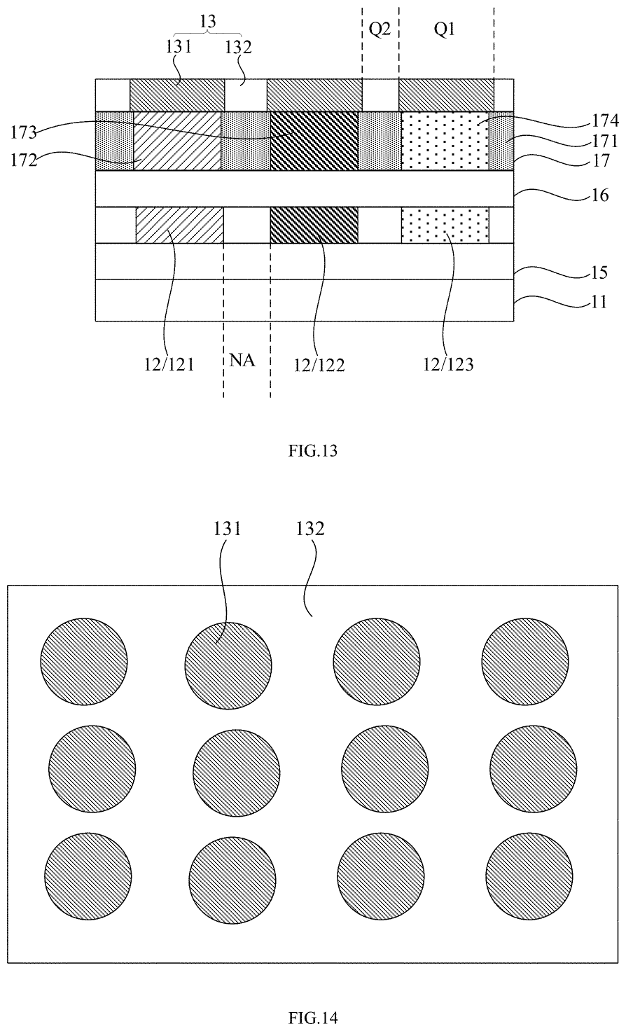

At step 3042, a second film 134 is formed on the first film 133 to obtain an intermediate structure as shown in FIG. 12.

As shown in FIG. 12, the second film 134 may include first areas Q1 arranged in an array and a second area Q2. The projection of the sub-pixels 12 on the base substrate 11 is located within a projection of the first areas Q1 on the base substrate 11, and a projection of the second area Q2 on the base substrate 11 is located within the projection of the non-display area NA on the base substrate 11. The second film 134 may be made of acrylic acid (AA) or acrylamide. In this embodiment, the second film 134 is made of AA.

At step 3043, the first areas Q1 and the second area Q2 are exposed, respectively, such that a material of the first film 133 is polymerized with a material of the second film 134 to obtain the hybrid film. A duration during which the first area Q1 is exposed is longer than a duration during which the second area Q2 is exposed. As shown in FIG. 13, the first hybrid sub-films 131 are respectively located in the first areas Q1 and the second hybrid sub-film 132 is located in the second area Q2.

In this embodiment, during exposure of the first areas and the second area, a digital exposure machine may be used to expose the first areas and the second area at the same time. The digital exposure machine may be an exposure machine without a mask, which may be programmed to achieve a series of split exposure. The digital exposure machine may have a light irradiance of 30 mW/cm² to 80 mW/cm². For example, the light irradiance of the digital exposure machine may be 30 mW/cm², 40 mW/cm², 50 mW/cm², 60 mW/cm², 70 mW/cm² or 80 mW/cm². In this embodiment, the light irradiance of the digital exposure machine may be 50 mW/cm². During exposure of the first areas and the second area, the longer the exposure duration is, the more exposure energy the first areas and the second area may receive.

In this embodiment, the digital exposure machine may be used to set different exposure durations for the first area Q1 and the second area Q2, respectively, and areas other than the first areas Q1 and the second area Q2 may not be exposed.

In an embodiment, the exposure duration of the first area Q1 may be 3 s to 13 s, for example, 3 s (seconds), 6 s, 10 s, or 13 s.

In an embodiment, the exposure duration of the second area Q2 may be 0.2 s to 1.1 s, for example, 0.2 s, 0.5 s, 0.8 s, or 1.1 s.

In this embodiment, acrylic acid (AA) may be polymerized on PET surface by a restricted photo-grafting technique, and polymer films with different grafting amounts may be obtained by controlling exposure durations. The principle is that as the exposure duration increases, a density of generated surface free radicals increases, and a grafting ratio of AA monomer increases accordingly. Therefore, by controlling the exposure in different areas, it is possible to obtain polyacrylic acid films with different degrees of polymerization on PET.

The grafting ratio refers to the percentage of free radical polymerization of acrylic acid. The higher the grafting ratio, the higher the content of polyacrylic acid on the PET film, and the denser the polyacrylic acid film. Polyacrylic acid molecule contains —COOH groups, which are hydrophilic groups.

It should be noted that the film on PET may include acrylic acid or hydrophilic monomer such as acrylamide. Considering process simplicity, unsaturated monomers that are more photosensitive may be selected.

Since PET film itself is highly hydrophobic, forming a polyacrylic acid film on the PET surface may improve surface energy of the PET surface, and reduce a contact angle of the PET film. When the degree of polymerization of polyacrylic acid on the PET surface is higher and denser, the hydrophilicity is better and the contact angle with a liquid is smaller. In order for the first area Q1 and the second area Q2 to have different surface energy, it is necessary for the first area Q1 and the second area Q2 to receive different exposure energy. In particular, the second area Q2 may receive low exposure energy (that is, have a short exposure duration), resulting in a low degree of polymerization of polyacrylic acid, and thus a poorer improvement in hydrophilicity, while the first area Q1 may have a long exposure duration, resulting in a high degree of polymerization of polyacrylic acid, and thus a better improvement in hydrophilicity.

In this embodiment, the exposure duration of the first area Q1 is 6 s, and the exposure duration of the second area Q2 is 0.8 s. In this way, surfaces with a large difference in surface energy may be formed in the first area Q1 and the second area Q2.

At step 305, the hybrid film 13 is coated with a photo-curable resin to form liquid droplets arranged in an array, where the liquid droplets are lens-shaped and located on the first hybrid sub-films, respectively.

In this embodiment, the photo-curable resin may be coated on the hybrid film 13. The photo-curable resin may be made of polymethyl methacrylate that is photosensitive and cured upon exposure to light.

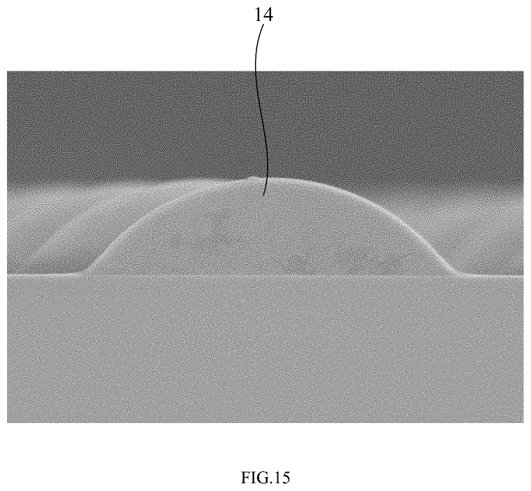

In this embodiment, as shown in FIG. 14, the first hybrid sub-film 131 may be circular in shape, but is not limited thereto. The second hybrid sub-film 132 surrounds the first hybrid sub-films 131. Since the contact angle of the liquid on the surface of the first hybrid sub-film 131 is less than the contact angle of the liquid on the surface of the second hybrid sub-film 132, the photo-curable resin may be gathered on the first hybrid sub-films 131 by a physical repulsion between interfaces with different contact angles, to form lens-shaped liquid droplets arranged in an array. That is, the liquid droplets are located on the first hybrid sub-films 131, respectively.

At step 306, the photo-curable resin is photo-cured to obtain lenses arranged in an array.

In this embodiment, after the liquid droplets are in the shape of lenses, the photo-curable resin is photo-cured to obtain the lenses 14 arranged in an array. The lenses 14 are located on the first hybrid sub-films 131, respectively.

As shown in FIG. 1, the projection of the sub-pixels 12 on the base substrate 11 is located within a projection of the first hybrid sub-films 131 on the base substrate 11. The lenses are located on the first hybrid sub-films 131, respectively. Light emitted from the sub-pixel 12 may pass through the lens 14, and the lens 14 has a convergence effect on the light emitted from the sub-pixel 12, such that brightness of the light emitted from the sub-pixel 12 can be increased.

In addition, the obtained lenses 14 arranged in an array were scanned with a scanning electron microscope (SEM), to obtain an SEM image as shown in FIG. 15. For the lens 14 as shown in FIG. 15, f is 18 μm, n₁ is 1.48, n₂ is 1.58, n₃ is 1, D is 10 μm, r is 8.25 μm, and H is 1.66 μm. However, parameters of an actually prepared lens may have other values, for example, D is 6.08 μm.

In this embodiment, the method may further include: after step 306, forming a protective layer 18 on the lenses 14 arranged in an array to obtain the display apparatus as shown in FIG. 1.

It should be noted that the display apparatus in embodiments of the present disclosure may include AR/VR display device, electronic paper, mobile phone, tablet computer, television, notebook computer, digital photo frame, navigator, and any other product or component with a display function.

Formation processes used in the above process may include, for example, a film formation process such as deposition and sputtering, and a patterning process such as etching.

It should be noted that in the drawings, sizes of layers and areas may be exaggerated for clarity of illustration. Furthermore, it may be understood that when an element or layer is referred to as being “on” another element or layer, it may be directly on the other element, or there may be an intermediate layer. Further, it may be understood that when an element or layer is referred to as being “under” another element or layer, it may be directly under the other element, or more than one intermediate layer or element may be present. In addition, it may be understood that when a layer or element is referred to as being “between” two layers or elements, it may be the only layer between the two layers or elements, or more than one intermediate layer or element may be present. Similar reference numerals indicate similar elements throughout.

In the present disclosure, terms “first” and “second” are used for descriptive purposes only, and are not to be understood as indicating or implying relative importance. Term “a plurality of” refers to two or more, unless expressly limited otherwise.

Other embodiments of the present disclosure will be apparent to those skilled in the art from consideration of the specification and practice of the disclosure disclosed herein. The present disclosure is intended to cover any variations, uses, or adaptive changes of the present disclosure that follow general principles thereof and include common knowledge or conventional technical means in the art that are not disclosed in the present disclosure. The specification and embodiments are considered as exemplary only, with a true scope and spirit of the present disclosure being indicated by the following claims.

It should be understood that the present disclosure is not limited to the precise structures that have been described above and shown in the drawings, and that various modifications and changes may be made without departing from the scope thereof. The scope of the present disclosure is limited only by the appended claims.

1. A method of preparing a lens array, comprising:
forming a hybrid film on a base substrate, the hybrid film comprising first hybrid sub-films arranged in an array and a second hybrid sub-film, and a contact angle of a liquid on a surface of the first hybrid sub-film being less than a contact angle of the liquid on a surface of the second hybrid sub-film;
coating the hybrid film with a photo-curable resin to form liquid droplets arranged in an array, the liquid droplets being lens-shaped and located on the first hybrid sub-films, respectively; and
photo-curing the photo-curable resin to obtain lenses arranged in an array, the lenses being located on the first hybrid sub-films, respectively.

2. The method of preparing the lens array of claim 1, wherein forming the hybrid film on the base substrate comprises:
forming a first film on the base substrate;
forming a second film on the first film, the second film comprising first areas arranged in an array and a second area; and
exposing the first areas and the second area, respectively, such that a material of the first film is polymerized with a material of the second film to obtain the hybrid film, a duration during which the first area is exposed being longer than a duration during which the second area is exposed, and the first hybrid sub-films being respectively located in the first areas and the second hybrid sub-film being located in the second area.

3. The method of preparing the lens array of claim 2, wherein
the first film is made of polyethylene terephthalate, polycarbonate or polyimide, and
the second film is made of acrylic acid or acrylamide.

4. The method of preparing the lens array of claim 2, wherein the duration during which the first area is exposed is 3 s to 13 s, and the duration during which the second area is exposed is 0.2 s to 1.1 s.

5. The method of preparing the lens array of claim 2, wherein a light irradiance for exposure of the first areas and the second area is 30 mW/cm² to 80 mW/cm².

6. The method of preparing the lens array of claim 1, wherein the contact angle of the liquid on the surface of the first hybrid sub-film is 10 degrees to 50 degrees, and the contact angle of the liquid on the surface of the second hybrid sub-film is 60 degrees to 90 degrees.

7. A method of preparing a display apparatus, comprising the method of preparing the lens array of claim 1.

8. The method of preparing the display apparatus of claim 7, further comprising:
after photo-curing the photo-curable resin to obtain the lenses arranged in an array, forming a protective layer on the lenses arranged in an array.

9. The method of preparing the display apparatus of claim 7, further comprising:
before forming the hybrid film on the base substrate, forming a plurality of sub-pixels arranged in an array on the base substrate, wherein a non-display area exists between adjacent sub-pixels; the hybrid film is located on a side of the plurality of sub-pixels arranged in an array away from the base substrate; and a projection of the sub-pixels on the base substrate is located within a projection of the first hybrid sub-films on the base substrate, and a projection of the second hybrid sub-film on the base substrate is located within a projection of the non-display area on the base substrate.

10. The method of preparing the display apparatus of claim 9, further comprising:
before forming the hybrid film on the base substrate, forming an encapsulation layer on the plurality of sub-pixels arranged in an array, the encapsulation layer being located between the sub-pixels and the hybrid film.

11. The method of preparing the display apparatus of claim 10, wherein
the plurality of sub-pixels comprise sub-pixels with at least one color; and
the method of preparing the display apparatus further comprises:
after forming the encapsulation layer on the plurality of sub-pixels arranged in an array, forming a color film on the encapsulation layer, wherein the color film is located between the encapsulation layer and the hybrid film, and comprises a black matrix and filters with at least one color; the black matrix is located between adjacent filters; colors of the sub-pixels are in a one-to-one correspondence with colors of the filters; and for a same color, the projection of the sub-pixels on the base substrate is located within a projection of the filters on the base substrate, and a projection of the black matrix on the base substrate is located within the projection of the non-display area on the base substrate.

12. A display apparatus, comprising:
a base substrate;
a plurality of sub-pixels arranged in an array and located on the base substrate, a non-display area existing between adjacent sub-pixels;
a hybrid film located on a side of the plurality of sub-pixels arranged in an array away from the base substrate, wherein the hybrid film comprises first hybrid sub-films arranged in an array and a second hybrid sub-film, and a contact angle of a liquid on a surface of the first hybrid sub-film is less than a contact angle of the liquid on a surface of the second hybrid sub-film; and a projection of the sub-pixels on the base substrate is located within a projection of the first hybrid sub-films on the base substrate, and a projection of the second hybrid sub-film on the base substrate is located within a projection of the non-display area on the base substrate; and
lenses arranged in an array and respectively located on the first hybrid sub-films.
